(19) United States
(12) Patent Application Publication
(10) Pub. No.: US 2025/0364256 A1
(43) Pub. Date: Nov. 27, 2025

(54) SEMICONDUCTOR PROCESSING TOOL AND METHODS OF OPERATION

(71) Applicant: Taiwan Semiconductor Manufacturing Company, Ltd., Hsinchu (TW)

(72) Inventor: Shang-Yu WANG, Changhua County (TW)

(21) Appl. No.: 19/293,387

(22) Filed: Aug. 7, 2025

Related U.S. Application Data
(62) Division of application No. 18/305,698, filed on Apr. 24, 2023.

(51) Int. Cl. H01L 21/304; G01R 33/035; H01L 21/3105; H01L 21/66; H01L 21/67; H10N 60/12

(52) U.S. Cl. CPC H01L 21/304; G01R 33/0354; H01L 21/31053; H01L 21/67253; H01L 22/26; H10N 60/12

(57) ABSTRACT

A planarization tool is configured to monitor one or more operational parameters of the planarization tool. The planarization tool may include a superconductor-based monitoring system that is configured to monitor a thickness of a layer on a semiconductor wafer that is processed by the planarization tool. The superconductor-based monitoring system may include a superconductor-based sensor that is configured to generate a signal that is based on an induced magnetic field through the layer on the semiconductor wafer. The signal may be provided to a controller of the planarization tool. The controller may determine a thickness of the layer based on the signal. The controller may provide one or more control signals to the polishing head to control one or more operational parameters such as a down force of the semiconductor wafer against the polishing pad and/or a rotational speed of the semiconductor wafer against the polishing pad, among other examples.

### RELATED APPLICATION

This application is a divisional of U.S. patent application Ser. No. 18/305,698, filed Apr. 24, 2023, which is incorporated herein by reference in its entirety.

### BACKGROUND

A layer, a substrate, or a semiconductor wafer may be planarized using a polishing or planarizing technique such as chemical mechanical polishing/planarization (CMP). A CMP operation may include depositing a slurry (or polishing compound) onto a polishing pad. A semiconductor wafer may be mounted to and secured by a carrier, which may rotate the semiconductor wafer as the semiconductor wafer is pressed against the polishing pad. The slurry and polishing pad act as an abrasive that polishes or planarizes one or more layers (e.g., metallization layers) of the semiconductor wafer as the semiconductor wafer is rotated. The polishing pad may also be rotated to ensure a continuous supply of slurry is applied to the polishing pad.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example planarization tool described herein.

FIGS. 2A-2C are diagrams of an example implementation of a processing chamber of the planarization tool described herein.

FIG. 3 is a diagram of an example implementation of using a superconductor-based monitoring system to monitor a thickness of a layer on a semiconductor wafer that is processed by the planarization tool described herein.

FIG. 4 is a diagram of an example implementation of using a superconductor-based monitoring system to monitor a thickness of a layer on a semiconductor wafer that is processed by the planarization tool described herein.

FIGS. 5A-5C are diagram of an example implementation of using a superconductor-based monitoring system to monitor a thickness of a layer on a semiconductor wafer during a planarization operation described herein.

FIG. 6 is a diagram of example components of a device described herein.

FIG. 7 is a flowchart of an example process associated with a planarization operation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A planarization tool may include one or more control systems that are configured to monitor one or more parameters of the planarization tool. The one or more parameters may include a down force (e.g., a magnitude of a force that is used to press a semiconductor wafer against a polishing pad of the planarization tool), a rotational velocity of the semiconductor wafer, a thickness of a layer on a semiconductor wafer that is being planarized by the planarization tool, and/or another parameter.

As the size of semiconductor devices that are manufactured on a semiconductor wafer decrease, so too do the sizes of structures and layers of the semiconductor devices. More granular and accurate monitoring and control over the semiconductor manufacturing processes may be needed to satisfy smaller and smaller manufacturing tolerances as the sizes of structures and layers of a semiconductor device decrease. In some cases, the control systems of a planarization tool may not provide sufficient granularity and accuracy of monitoring and control over the semiconductor manufacturing processes performed by the planarization tool. As a result, the planarization tool may be unable to achieve or satisfy smaller and smaller manufacturing tolerances as the sizes of structures and layers of a semiconductor device decreases. This can lead to manufacturing defects in semiconductor devices processed by the planarization tool and/or reduced yield of semiconductor devices processed by the planarization tool, among other examples.

In some implementations described herein, semiconductor wafers are processed using a planarization tool described herein. The planarization tool includes a polishing head that is configured to support and secure a semiconductor wafer during a planarization operation in which the polishing head presses the semiconductor wafer against a polishing pad that is supported by a platen of the planarization tool.

The planarization tool is further configured to monitor one or more operational parameters of the planarization tool. For example, the planarization tool may include a superconductor-based monitoring system that is configured to monitor a thickness of a layer on a semiconductor wafer that is processed by the planarization tool. The superconductor-based monitoring system includes a superconducting quantum interface device (SQUID) configured to generate a signal that is based on an induced magnetic field through the layer on the semiconductor wafer. The signal may be provided to a CMP controller of the planarization tool. The CMP controller may determine a thickness of the layer based on the signal. The CMP controller may provide one or more control signals to the polishing head to control one or more operational parameters such as a down force of the semiconductor wafer against the polishing pad and/or a rotational speed of the semiconductor wafer against the polishing pad, among other examples.

The superconductor-based monitoring system is capable of directly measuring the induced magnetic field, which may enable more granular and precise monitoring of the thickness of the layer on the semiconductor wafer that is processed by the planarization tool relative to other types of monitoring systems (e.g., coil sensor-based monitoring systems) that use indirect electromagnetic induction. This may enable more granular and precise control of operational parameters of the planarization tool, which may reduce process variation for the planarization tool and may enable the planarization tool to achieve or satisfy smaller and smaller manufacturing tolerances as the sizes of structures and layers of a semiconductor device decreases. In this way, the superconductor-based monitoring system may reduce manufacturing defects in semiconductor devices processed by the planarization tool and/or may increase the yield of semiconductor devices processed by the planarization tool, among other examples.

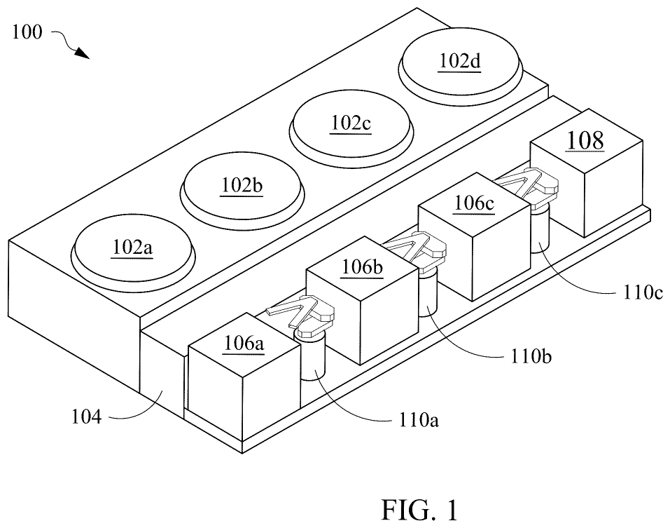

FIG. 1 is a diagram of an example planarization tool 100 described herein. The planarization tool 100 includes a semiconductor processing tool that is capable of polishing or planarizing a semiconductor wafer, a semiconductor device, and/or another type of semiconductor substrate. The planarization tool 100 includes one or more processing chambers 102a-102d in which layers and/or structures of a semiconductor wafer are polished or planarized. In some implementations, a processing chamber 102 is configured to polish or planarize a surface (or a layer or structure) of a semiconductor wafer with a combination of chemical and mechanical forces (e.g., chemical etching and free abrasive polishing). The planarization tool 100 is configured to utilize an abrasive and corrosive chemical slurry in conjunction with a polishing pad and retaining ring (e.g., typically of a greater diameter than the semiconductor wafer) in a processing chamber 102. To perform a CMP operation, the planarization tool 100 presses the polishing pad against the semiconductor wafer in the processing chamber 102 using a dynamic polishing head that is held in place by the retaining ring. The dynamic polishing head may rotate with different axes of rotation to remove material and even out any irregular topography of a layer or a structure of the semiconductor wafer, thereby making the layer or a structure of the semiconductor wafer flat or planar.

The planarization tool 100 includes a transfer chamber 104 in which semiconductor wafers are transferred to and from the processing chamber(s) 102. Moreover, semiconductor wafers are transferred between the transfer chamber 104 and one or more cleaning chambers 106a-106c included in the planarization tool 100. A cleaning chamber 106 (also referred to as a CMP cleaning chamber or a post-CMP cleaning chamber) is a component of the planarization tool 100 that is configured to perform a post-CMP cleaning operation to clean or remove residual slurry and/or removed material from a semiconductor wafer that has undergone a CMP operation. In some implementations, the planarization tool 100 includes a plurality of cleaning chambers 106, and the planarization tool 100 is configured to process a semiconductor wafer through a plurality of sequential post-CMP cleaning operations in the plurality of cleaning chambers 106. As an example, the planarization tool 100 may process a semiconductor wafer in a first post-CMP cleaning operation in a cleaning chamber 106a, may process the semiconductor wafer in a second post-CMP cleaning operation in a cleaning chamber 106b, may process the semiconductor wafer in a third post-CMP cleaning operation in a cleaning chamber 106c, and so on.

A cleaning chamber 106 cleans a semiconductor wafer using a cleaning agent such as isopropyl alcohol (IPA), a chemical solution that includes a plurality of cleaning chemicals, and/or another type of cleaning agent. The planarization tool 100 includes one or more types of cleaning chambers 106. Each type of cleaning chamber 106 is configured to clean a semiconductor wafer using a different type of cleaning device. In some implementations, a cleaning chamber 106 includes a brush-type cleaning chamber. A brush-type cleaning chamber is a cleaning chamber that includes one or more cleaning brushes (or roller brushes) that are configured to spin or rotate to brush-clean a semiconductor wafer. In some implementations, a cleaning chamber 106 includes a pen-type cleaning chamber. A pen-type cleaning chamber is a cleaning chamber that includes a cleaning pen (or cleaning pencil) that is configured to provide fine-tuned and detailed cleaning of a semiconductor substrate.

In some implementations, the cleaning chambers 106 of the planarization tool 100 are arranged such that a semiconductor wafer is first processed in one or more brush-type cleaning chambers (e.g., to remove a large amount of removed material and residual slurry from the semiconductor wafer), and is then processed in a pen-type cleaning chamber (e.g., to provide detailed cleaning of structures and/or recesses in the semiconductor wafer). As an example, the cleaning chambers 106a and 106b may be configured as brush-type cleaning chambers, and cleaning chamber 106c may be configured as a pen-type cleaning chamber.

The planarization tool 100 includes a rinsing chamber 108 that is configured to rinse a semiconductor wafer after one or more post-CMP cleaning operations. The rinsing chamber 108 rinses a semiconductor wafer to remove residual cleaning agent from the semiconductor wafer. The rinsing chamber 108 is configured to use a rinsing agent, such as deionized water (DIW) or another type of rinsing agent, to rinse a semiconductor wafer. Semiconductor wafers are transferred to the rinsing chamber 108 from a cleaning chamber 106 directly or through the transfer chamber 104. In some implementations, a semiconductor wafer is processed in a drying operation in the rinsing chamber 108, in which the semiconductor wafer is dried to prevent oxidation and/or other types of contamination of the semiconductor wafer.

The planarization tool 100 includes a plurality of transport devices 110a-110c. The transport devices 110 include robot arms or other types of transport devices that are configured to transfer semiconductor wafers between the processing chamber(s) 102, the transfer chamber 104, the cleaning chamber(s) 106, and/or the rinsing chamber 108.

As indicated above, FIG. 1 is provided as an example. Other examples may differ from what is described with regard to FIG. 1.

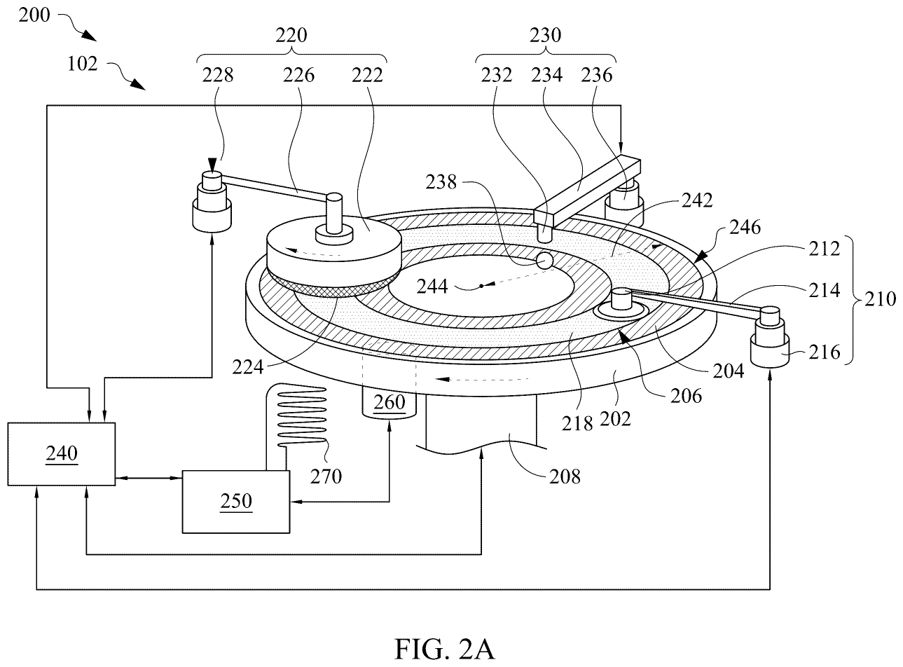

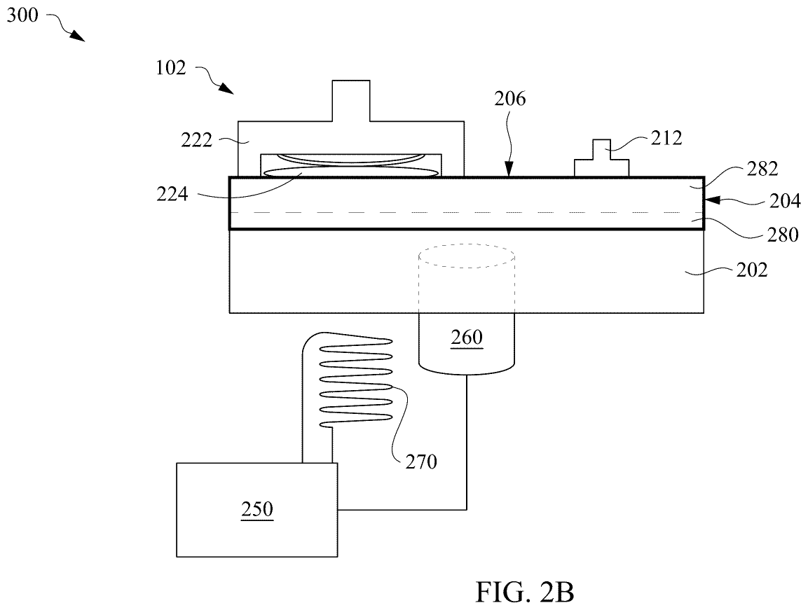

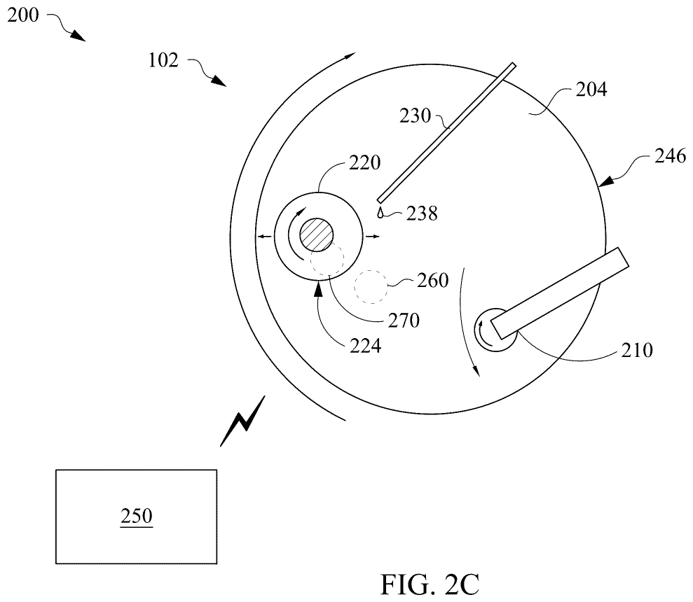

FIGS. 2A-2C are diagrams of an example implementation 200 of a processing chamber 102 of the planarization tool 100 described herein. In particular, FIGS. 2A-2C illustrate views inside the processing chamber 102.

FIG. 2A illustrates a perspective view inside the processing chamber 102. As shown in FIG. 2A, the processing chamber 102 includes various subsystems including a conditioner 210, a wafer carrier 220, a slurry system 230, a motor assembly 240, and a CMP controller 250. The processing chamber 102 further includes a rotating platen 202 and a polishing pad 204. The polishing pad 204 is mounted on the rotating platen 202 and has a polishing surface 206. The rotating platen 202 is further coupled to a drive shaft 208.

The conditioner 210 includes a conditioning disk 212 which can be pivoted via an arm 214. The arm 214 is electrically connected to the motor assembly 240 through a shaft 216. The arm 214 is driven by the shaft 216 to move, for example, in a swing motion over a range 218 in a planarization operation (e.g., a CMP operation). Therefore, the conditioning disk 212 travels along the swing motion to condition different portions of the polishing surface 206. The conditioning disk 212 may be configured to rotate about an axis to restore asperities to the polishing surface 206 as the planarization operation makes the polishing surface 206 smoother. That is, in order to retain the material removal qualities of the polishing pad 204, the conditioning disk 212 is used to maintain roughness on the polishing surface 206 that would otherwise be lost during the planarization operation. The conditioning disk 212 carries an abrasive pad that may include, for example, a diamond abrasive.

The wafer carrier 220 includes a polishing head 222 for mounting and securing a semiconductor wafer 224. The semiconductor wafer 224 may be mounted and secured to the polishing head 222 by a vacuum force or another type of securing force. The semiconductor wafer 224 is mounted to the polishing head 222 such that a surface of the semiconductor wafer 224 (e.g., a polishing surface, a processing surface, an active surface, a device surface) that is to be processed is orientated to face the polishing surface 206. The polishing head 222 may also be pivoted via an arm 226. The arm 226 is electrically connected to the motor assembly 240 through a shaft 228. In some implementations, the arm 226 may also be driven by the shaft 228 to move in a swing motion during the planarization operation. The polishing head 222 is configured to rotate about an axis of the polishing head 222 (e.g., an axis that is approximately perpendicular to the polishing surface 206) in the planarization operation.

The slurry system 230 includes a slurry supply 232 which can be pivoted via an arm 234. The arm 234 is electrically connected to the motor assembly 240 through a shaft 236. In some implementations, the arm 234 may also be driven by the shaft 236 to move in a swing motion in the planarization operation. The slurry system 230 can provide slurry 238 which may include an abrasive compound and a fluid such as deionized water, or a liquid cleaner such as potassium hydroxide (KOH), onto the polishing surface 206 of the polishing pad 204 before wafer planarization occurs. In an example, a flow rate of the slurry 238 may be in a range of approximately 50 milliliters (ml)/minute to approximately 350 ml/minute. However, other values for the range are within the scope of the present disclosure.

In the planarization operation, the motor assembly 240 rotates the platen 202 and the polishing pad 204 via the drive shaft 208. The slurry system 230 dispenses the slurry 238 onto the polishing surface 206. As the polishing pad 204 rotates, the conditioning disk 212 is rotated about a disk axis of the conditioning disk 212 and is driven to swing horizontally above the polishing surface 206 such that the conditioning disk 212 can condition the polishing surface 206 of the polishing pad 204. In some implementations, the conditioning disk 212 iteratively conditions the inner portions and the outer portions of the polishing surface 206. The motor assembly 240 also rotates a semiconductor wafer 224, mounted and secured by the wafer carrier 220, through the arm 226 and the shaft 228. A down-force is controlled by the CMP controller 250 to move the active surface of the semiconductor wafer 224 onto the polishing surface 206. In this configuration, the conditioning disk 212 scratches or roughs up the polishing surface 206 of the polishing pad 204 continuously during the CMP process to promote consistent uniform planarization. The combination of motions of the conditioner 210, the wafer carrier 220, and the slurry system 230 planarizes the active surface of the semiconductor wafer 224 until an endpoint for the CMP process is reached, which may include a particular time duration of the CMP process, a particular amount of material removed from the semiconductor wafer 224, or another endpoint.

In some implementations, the polishing surface 206 includes a plurality of groove segments and/or geometric patterns formed by the plurality of groove segments configured in a groove region 242 of the polishing pad 204. During the CMP process, all or a portion of the plurality of groove segments and/or geometric patterns formed by the plurality of groove segments impede a trajectory of the slurry (hereinafter referred to as a slurry trajectory). Specifically, all or a portion of the plurality of groove segments and/or geometric patterns formed by the plurality of groove segments are configured to impede a radial flow of the slurry 238 from a center 244 of the polishing pad 204 (or from an area of the polishing pad 204 in which the slurry 238 is dispensed) to a polishing pad outer edge 246. Impeding the slurry trajectory promotes retention of the slurry 238 on the polishing surface 206 of the polishing pad 204. By impeding the slurry trajectory, a retention time or duration of time the slurry is present on the polishing pad is increased. Increasing the retention of the slurry results in a more predictable and controlled CMP process and reduces slurry waste.

In some implementations, the slurry 238 is dispensed onto the groove region 242 of the polishing pad 204. The rotation of the polishing pad 204 creates forces that direct the slurry 238 toward the polishing pad outer edge 246. The geometric patterns formed by the plurality of groove segments in the groove region 242 of the polishing pad 204 alters the slurry trajectory across the polishing pad 204. As described herein, all or a portion of the plurality of groove segments and/or geometric patterns formed by the plurality of groove segments are configured to increase a retention time or duration of time the slurry 238 is present on the polishing pad 204.

As further shown in FIG. 2A, the planarization tool 100 may include a superconductor-based monitoring system. The superconductor-based monitoring system may be configured to monitor a thickness of a layer on the semiconductor wafer 224 that is processed by the planarization tool 100 in the processing chamber 102. The superconductor-based monitoring system may include and/or may correspond to a combination of the CMP controller 250, a superconductor-based magnetometer device 260, and a conductive coil 270, among other components. The superconductor-based magnetometer device 260 and the conductive coil 270 may be communicatively coupled with the CMP controller 250.

The superconductor-based magnetometer device 260 may include a superconducting quantum interference device (SQUID) and/or another type of magnetometer that is configured to monitor and/or measure an induced magnetic field. The induced magnetic field may be induced in a layer (e.g., a metal layer, a conductive layer) on the semiconductor wafer 224 that is planarized by the planarization tool 100. The superconductor-based magnetometer device 260 may communicate with the CMP controller 250 to provide one or more signals to the CMP controller 250. This enables the CMP controller 250 to monitor the thickness of the layer on the semiconductor wafer 224 during a planarization operation performed by the planarization tool 100. In particular, the CMP controller 250 may monitor the thickness of the layer based on the one or more signals received from the superconductor-based magnetometer device 260.

The induced magnetic field may be generated as a result of eddy currents formed in the layer on the semiconductor wafer 224. The eddy currents may form as a result of an applied magnetic field that is applied to the layer on the semiconductor wafer 224. An electrical current may be provided through the conductive coil 270, which may generate the applied magnetic field. The CMP controller 250 may provide one or more signals to the conductive coil 270 to cause the electrical current to flow through the conductive coil 270. The conductive coil 270 may include a coil of copper (Cu) wire, a gold (Au) conductor, a silver conductor (Ag), and/or another type of conductive wire. In some implementations, the conductive coil 270 comprises a superconductive material, such as niobium tin (Nb₃Sn), niobium titanium (NbTi), barium copper oxide (BCO), and/or rare earth BCO ((RE)BCO), among other examples.

FIG. 2B is a cross-sectional view inside the processing chamber 102 described herein. As shown in FIG. 2B, the polishing pad 204 may include a pad base 280 and a groove layer 282. In some implementations, groove layer 282 may be supported by the pad base 280, which may be formed integrally with groove layer 282 or may be formed separately from the groove layer 282. The polishing pad 204 may have a circular disk shape with the polishing surface 206 formed thereon. The groove layer 282 includes the polishing surface 206 thereon. The groove layer 282 may be formed from any material suitable for polishing an article to be polished, such as a semiconductor wafer 224. Examples of materials for polishing groove layer 282 include various polymer plastics, such as a polyurethane, polybutadiene, polycarbonate and polymethylacrylate, among other examples.

As shown in FIG. 2B, in some implementations, the superconductor-based magnetometer device 260 is located and/or positioned below and/or under the polishing pad 204 and the platen 202 supporting the polishing pad 204. In some implementations, the superconductor-based magnetometer device 260 is located and/or positioned above and/or over the polishing pad 204 and the platen 202 supporting the polishing pad 204. For example, the superconductor-based magnetometer device 260 may be mounted to the wafer carrier 220, the polishing head 222, and/or another location above and/or over the polishing pad 204 and the platen 202.

As shown in FIG. 2B, in some implementations, the conductive coil 270 is located and/or positioned below and/or under the polishing pad 204 and the platen 202 supporting the polishing pad 204. In some implementations, the conductive coil 270 is located and/or positioned above and/or over the polishing pad 204 and the platen 202 supporting the polishing pad 204. For example, the conductive coil 270 may be mounted to the wafer carrier 220, the polishing head 222, and/or another location above and/or over the polishing pad 204 and the platen 202.

FIG. 2C is a diagram of an example planarization operation performed in the processing chamber 102. In some implementations, the wafer carrier 220 mounts and secures the semiconductor wafer 224. The slurry system 230 applies the slurry 238 to the polishing pad 204. The conditioner 210 spreads the slurry 238 across the polishing pad 204 while the polishing pad 204 is in motion. In the planarization operation, the polishing pad 204 and the wafer carrier 220 rotate and/or oscillate to perform a planarization of the semiconductor wafer 224. The planarization operation removes an amount, for example the excess thickness, of a layer on the semiconductor wafer 224. The planarization operation includes dispensing the slurry 238 onto the polishing pad 204, and rotating the polishing pad 204, where rotation of the polishing pad 204 results in a slurry trajectory of the slurry 238 radially outward toward the polishing pad outer edge 246 of the polishing pad 204.

In the planarization operation, a thickness of a layer on the semiconductor wafer 224 may be monitored using the superconductor-based magnetometer device 260. The conductive coil 270 may generate an applied magnetic field, which induces an eddy current in the layer on the semiconductor wafer 224. The eddy current results in an induced magnetic field being generated, and the superconductor-based magnetometer device 260 measures the induced magnetic field. The superconductor-based magnetometer device 260 may provide a signal to the CMP controller 250 based on a result of the measurement of the induced magnetic field, and the CMP controller 250 may determine the thickness of the layer based on the signal.

As indicated above, FIGS. 2A-2C are provided as examples. Other examples may differ from what is described with regard to FIGS. 2A-2C.

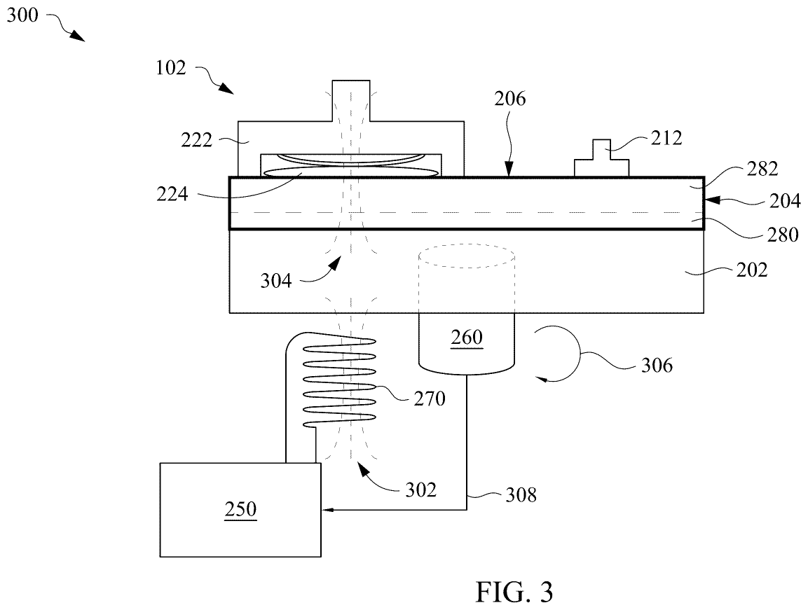

FIG. 3 is a diagram of an example implementation 300 of using a superconductor-based monitoring system to monitor a thickness of a layer on a semiconductor wafer 224 that is processed by the planarization tool 100 described herein. FIG. 3 illustrates a view inside the processing chamber 102 of the planarization tool 100.

As shown in FIG. 3, the conductive coil 270 may generate an applied magnetic field 302. The applied magnetic field 302 may be generated as a result of an electrical current flowing through the conductive coil 270. The magnitude (e.g., field strength or intensity) of the applied magnetic field 302 may be based on a type of current that is used to generate the applied magnetic field 302, a quantity of coils in the conductive coil 270, a type of conductor or coil used for the applied magnetic field 302, and/or another parameter or attribute of the conductive coil 270. In some implementations, a direct current (DC) is provided through the conductive coil 270 to generate the applied magnetic field 302. In some implementations, an alternating current (AC) is provided through the conductive coil 270 to generate the applied magnetic field 302.

During the planarization operation, the semiconductor wafer 224 may pass through the applied magnetic field 302, which causes an eddy current to be induced in the layer on the semiconductor wafer 224. The movement of the semiconductor wafer 224 (e.g., the rotation of the semiconductor wafer 224 by the polishing head 222) through the applied magnetic field 302 causes the magnetic flux through the layer on the semiconductor wafer 224 to change. The changing magnetic flux creates a circular electric field in the layer on the semiconductor wafer 224, which is the eddy current.

The magnitude (e.g., field strength or intensity) of the eddy current induced in the layer on the semiconductor wafer 224 may be based on the magnitude of the applied magnetic field 302, the distance between the conductive coil 270 and the semiconductor wafer 224, the rotational velocity of the semiconductor wafer 224, and/or the thickness of the layer on the semiconductor wafer 224, among other examples. In some implementations, the magnitude of the applied magnetic field 302 may be included in a range of greater than approximately 0 Tesla to approximately 10 Tesla. However, other values for the range are within the scope of the present disclosure. In some implementations, the rotational velocity of the semiconductor wafer 224 may be included in a range of approximately 30 revolutions per minute to approximately 300 revolutions per minute. However, other values for the range are within the scope of the present disclosure.

In some implementations, the magnitude of the applied magnetic field 302, the rotational velocity of the semiconductor wafer 224, and the distance between the conductive coil 270 and the semiconductor wafer 224 may be maintained approximately constant during the planarization operation. In this way, the thickness of the layer on the semiconductor wafer 224 is one of the only variables that changes during the planarization operation, which enables the thickness of the layer on the semiconductor wafer 224 to be determined and monitored.

The eddy current (e.g., the circular current) induced in the layer on the semiconductor wafer 224 causes an induced magnetic field 304 to be generated. The magnitude (e.g., the field strength or intensity) of the induced magnetic field 304 is based on the magnitude of the eddy current induced in the layer on the semiconductor wafer 224. As described above, the magnitude of the applied magnetic field 302, the rotational velocity of the semiconductor wafer 224, and the distance between the conductive coil 270 and the semiconductor wafer 224 may be maintained approximately constant during the planarization operation. Thus, the thickness of the layer on the semiconductor wafer 224 is the main parameter that influences the magnitude of the eddy current in the layer on the semiconductor wafer 224. Accordingly, since the field strength of the induced magnetic field 304 is based on the magnitude of the eddy current, the field strength of the induced magnetic field 304 is based on the thickness of the layer on the semiconductor wafer 224.

As shown in FIG. 3, at 306, the superconductor-based magnetometer device 260 may detect and measure the induced magnetic field 304. The superconductor-based magnetometer device 260 may generate a signal 308 based on the induced magnetic field 304. In particular, the superconductor-based magnetometer device 260 may generate the signal 308 based on the magnitude (e.g., the field strength or intensity) of the induced magnetic field 304. The signal 308 may include a voltage signal, a current signal, a resistance signal, a digital communication, and/or another type of electrical signal. The signal 308 may be provided from the superconductor-based magnetometer device 260 to the CMP controller 250. In some implementations, the superconductor-based magnetometer device 260 may be positioned such that a distance between the superconductor-based magnetometer device 260 and the semiconductor wafer 224 is included in a range of approximately 1 micron to approximately 100 millimeters to enable sufficient detection of the induced magnetic field 304 while minimizing the amount of interference with detection and measurement of the induced magnetic field 304. However, other values for the range are within the scope of the present disclosure.

As indicated above, the field strength of the induced magnetic field 304 is based on the thickness of the layer on the semiconductor wafer 224. Accordingly, the signal 308 may be based on the field strength of the induced magnetic field 304, and may be an indicator of the thickness of the layer on the semiconductor wafer 224. The CMP controller 250 may receive the signal 308 and may determine the thickness of the layer on the semiconductor wafer 224 based on the signal 308.

As indicated above, FIG. 3 is provided as an example. Other examples may differ from what is described with regard to FIG. 3.

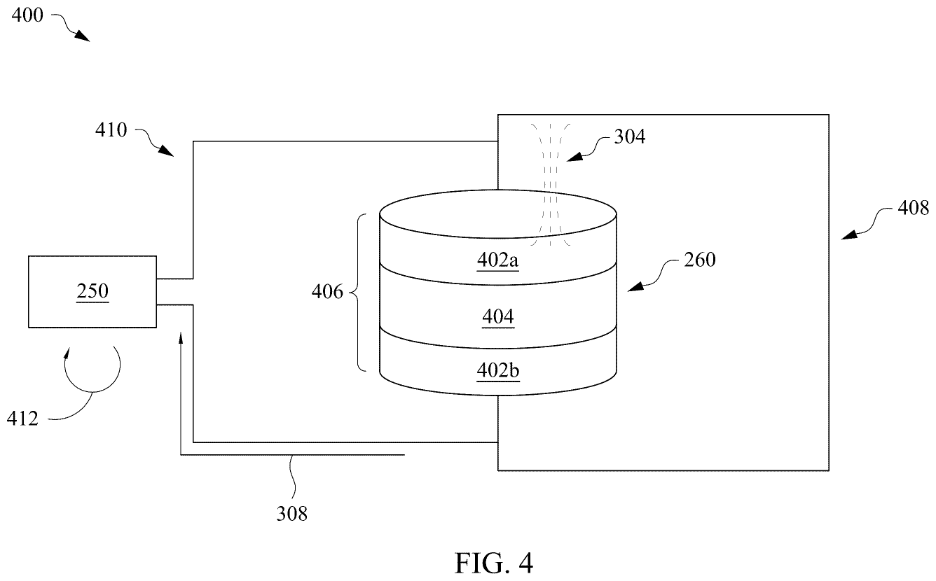

FIG. 4 is a diagram of an example implementation 400 of using a superconductor-based monitoring system to monitor a thickness of a layer on a semiconductor wafer 224 that is processed by the planarization tool 100 described herein.

As shown in FIG. 4, the superconductor-based magnetometer device 260 of the superconductor-based monitoring system may include a plurality of superconductor elements, including a superconductor element 402a and a superconductor element 402b. The superconductor-based magnetometer device 260 may further include an insulator layer 404.

The superconductor elements 402a and 402b may each include one or more superconductive materials, such as niobium tin (Nb₃Sn), niobium titanium (NbTi), barium copper oxide (BCO), and/or rare earth BCO ((RE)BCO), among other examples. The insulator layer 404 may include an electrically insulating material, such as a dielectric, a polymer, a ceramic, and/or a glass, among other examples.

In some implementations, the superconductor elements 402a and 402b may each have a thickness that is included in a range of approximately 1 nanometer to approximately 1 millimeter to provide sufficient structural rigidity for the superconductor-based magnetometer device 260 without unduly increasing the cooling requirements for the superconductor-based magnetometer device 260. However, other values for the range are within the scope of the present disclosure. In some implementations, a thickness of the insulator layer 404 is included in a range of approximately 1 angstrom to approximately 100 nanometers to facilitate quantum tunnelling between the superconductor element 402a and the superconductor element 402b while providing sufficient structural rigidity for the superconductor-based magnetometer device 260. However, other values for the range are within the scope of the present disclosure.

The superconductor element 402a, the superconductor element 402b, and the insulator layer 404 may be configured as a Josephson junction 406 (also referred to as a superconductor-insulator-superconductor (SIS) junction) in which the insulator layer 404 is included between the superconductor element 402a and the superconductor element 402b. The Josephson junction 406 operates based on the Josephson effect, where an electrical current 408 (e.g., a supercurrent) is produced without an applied voltage based on the proximity of the superconductor element 402a and the superconductor element 402b, and based on the insulator layer 404 being located between the superconductor element 402a and the superconductor element 402b.

In some implementations, the superconductor element 402a and the superconductor element 402b are arranged in loops that are electrically isolated by the insulator layer 404. This configuration is referred to as a SQUID, and this configuration enables direct detection and measurement of an induced magnetic field 304. In the absence of the induced magnetic field 304, the electrical current 408 continuously flows through the Josephson junction 406. When the induced magnetic field 304 is generated and applied to the Josephson junction 406 of the superconductor-based magnetometer device 260, a screening current flows through the Josephson junction 406. When a combination of the screening current and the electrical current 408 satisfies a threshold current (I_{c}), a signal 308 (e.g., a voltage signal) is generated and provided to the CMP controller 250 through a voltage detection circuit 410.

At 412, the voltage detection circuit 410 enables the CMP controller 250 to perform a measurement of the signal 308, which may correspond to (or may be based on) a voltage drop across the Josephson junction 406 of the superconductor-based magnetometer device 260. A magnitude of the voltage drop may be based on a field strength of the induced magnetic field 304, which may be based on a thickness of a layer on a semiconductor wafer 224 that is processed by the planarization tool 100 in a planarization operation.

Using the superconductor-based magnetometer device 260 to directly detect and measure the induced magnetic field 304 enables the CMP controller 250 to determine the thickness of the layer on the semiconductor wafer 224 with a high level of precision. The quantum-level operation of the superconductor-based magnetometer device 260 enables the superconductor-based magnetometer device 260 to directly detect and measure the induced magnetic field 304 across a wide range of magnetism (e.g., from approximately 5×10⁻¹⁸ Tesla to approximately 5 Tesla, or another range), which enables the superconductor-based magnetometer device 260 to detect changes in the induced magnetic field 304 that are less than the geomagnetism (e.g., approximately 1×10⁻⁵ Tesla) in the surrounding environment. This highly granular level of detection enables the CMP controller 250 to determine and/or identify angstrom-level changes in the thickness of the layer on the semiconductor wafer 224, which enables the CMP controller 250 to modify parameters of a planarization operation for the layer to achieve a high level of uniformity (e.g., angstrom-level uniformity) for the layer and/or to determine a completion time for the planarization operation, among other examples.

In some implementations, a processing chamber 102 of the planarization tool 100 may include a plurality of superconductor-based magnetometer devices 260 that are configured to determine an overall profile for a layer on a semiconductor wafer 224 that is processed in the processing chamber 102. The plurality of superconductor-based magnetometer devices 260 may be dispersed across the polishing pad 204 in the processing chamber 102 to enable measurement of the thickness of a layer in different regions on the semiconductor wafer 224 to determine the overall profile for the layer.

As indicated above, FIG. 4 is provided as an example. Other examples may differ from what is described with regard to FIG. 4.

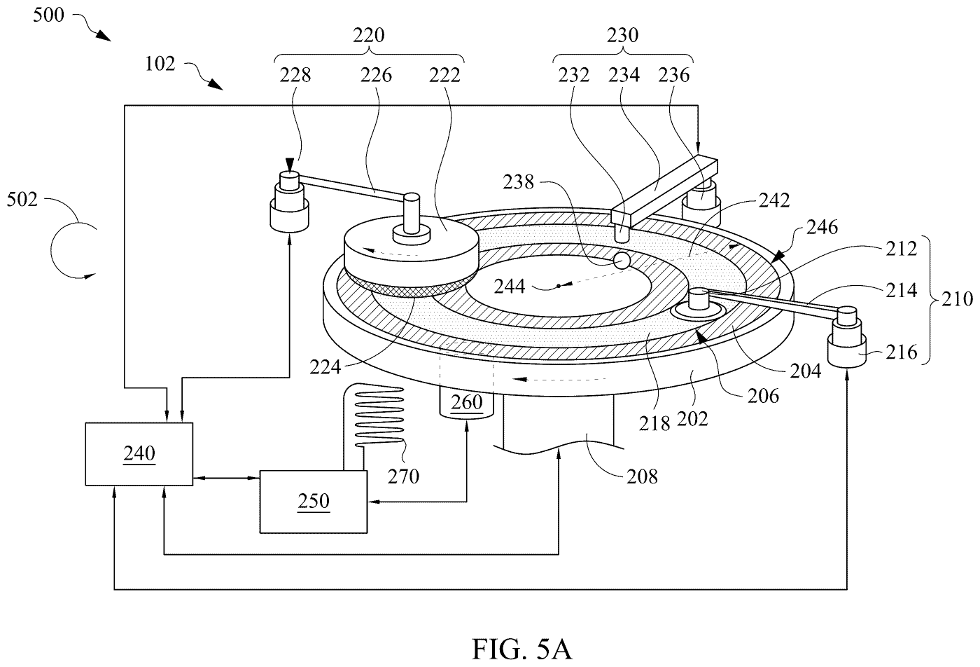

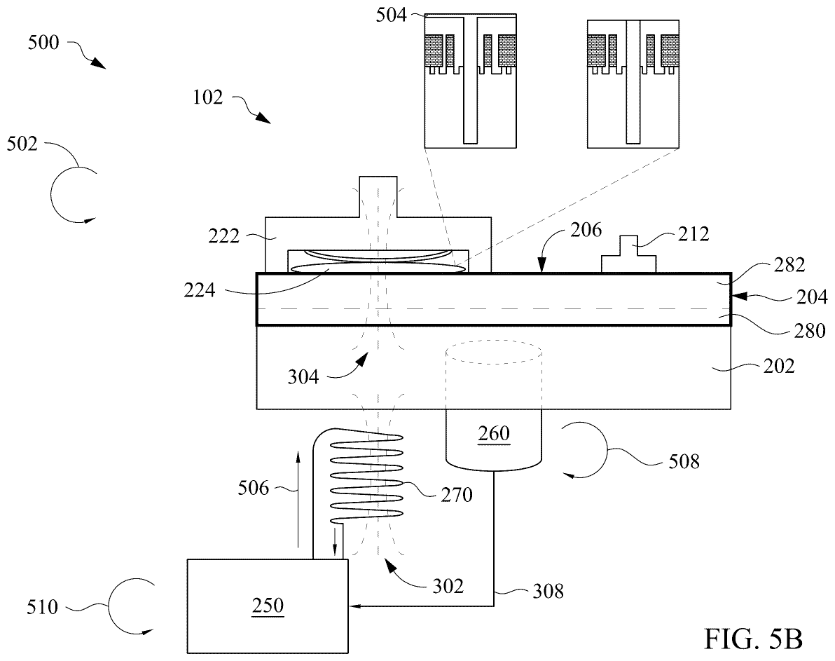

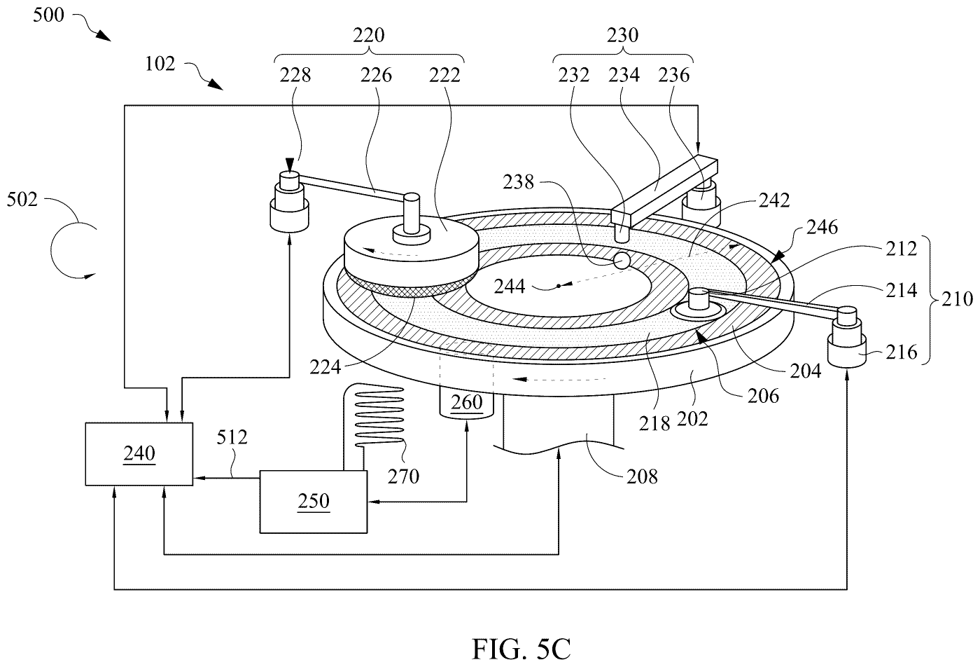

FIGS. 5A-5C are diagrams of an example implementation 500 of using a superconductor-based monitoring system to monitor a thickness of a layer on a semiconductor wafer 224 during a planarization operation 502 described herein. The planarization operation 502 may be performed by the planarization tool 100. Using the superconductor-based monitoring system to monitor the thickness of the layer on the semiconductor wafer 224 during the planarization operation 502 enables the CMP controller 250 of the planarization tool 100 to precisely control one or more parameters of the planarization operation 502 and/or to determine a completion time for the planarization operation 502, among other examples.

Turning to FIG. 5A, the planarization operation 502 may include securing the semiconductor wafer 224 to the polishing head 222 of the wafer carrier 220 of the planarization tool 100. The slurry system 230 applies the slurry 238 to the polishing pad 204. The conditioner 210 spreads the slurry 238 across the polishing pad 204 while the polishing pad 204 is in motion. In the planarization operation 502, the polishing pad 204 and the wafer carrier 220 rotate and/or oscillate to perform a planarization of the semiconductor wafer 224. The planarization operation includes dispensing the slurry 238 onto the polishing pad 204, and rotating the polishing pad 204, where rotation of the polishing pad 204 results in a slurry trajectory of the slurry 238 radially outward toward the polishing pad outer edge 246 of the polishing pad 204.

As shown in FIG. 5B, in the planarization operation 502, the planarization tool 100 removes an amount, for example the excess thickness, of a layer 504 on the semiconductor wafer 224. Thus, the thickness of the layer 504 is gradually reduced during the planarization operation 502. As further shown in FIG. 5B, operations 506-510 may be performed to determine and monitor the thickness of the layer 504, using the superconductor-based magnetometer device 260, during the planarization operation 502.

The layer 504 may include a metallization layer and/or another type of electrically conductive layer. For example, the layer 504 may include a via, a plug, a contact, a trench, a through silicon via (TSV), a through insulator via (TIV), and/or another type of metallization layer. The layer 504 may include one or more electrically conductive materials, such as copper (Cu), cobalt (Co), tungsten (W), titanium (Ti), tantalum (Ta), aluminum (Al), ruthenium (Ru), an alloy thereof, and/or another electrically conductive material. The starting thickness of the layer 504 at the beginning of the planarization operation 502 may be on the order of millimeters, nanometers, and/or angstroms, among other examples.

At 506, the CMP controller may provide one or more signals to the conductive coil 270 to cause an electrical current to flow through the conductive coil 270. The electrical current flowing through the conductive coil 270 causes an applied magnetic field 302 to be generated. The semiconductor wafer 224 passes through the applied magnetic field 302. The electrically conductive property of the layer 504 results in an interaction between the layer 504 and the applied magnetic field 302. In particular, the combination of the rotation of the semiconductor wafer 224 and the applied magnetic field 302 cause an eddy current to be induced in the layer 504 on the semiconductor wafer 224. The eddy current, in turn, causes an induced magnetic field 304 to be generated.

At 508, the superconductor-based magnetometer device 260 detects the induced magnetic field 304. The superconductor-based magnetometer device 260 generates a signal 308 (e.g., a voltage signal, a current signal) based on the magnitude (e.g., the field strength or intensity) of the induced magnetic field 304 and provides the signal 308 to the CMP controller 250. The CMP controller 250 may receive the signal 308 and may perform one or more measurements of the signal 308 to determine a thickness of the layer 504 on the semiconductor wafer 224. The CMP controller 250 may continue to monitor the thickness of the layer 504, and/or to detect or monitor changes in the thickness of the layer 504, by performing subsequent measurements of the signal 308 during the planarization operation 502.

At 510, the CMP controller 250 may determine, using the superconductor-based magnetometer device 260, one or more modified parameters for the planarization operation 502 based on monitoring the thickness of the layer 504 on the semiconductor wafer 224 during the planarization operation 502. For example, the CMP controller 250 may determine the one or more modified parameters for the planarization operation 502 based on changes in the thickness of the layer 504 during the planarization operation 502, as monitored during the planarization operation 502 using the superconductor-based magnetometer device 260.

In some implementations, the CMP controller 250 determines a modified rotational velocity for the semiconductor wafer 224 based on monitoring the thickness of the layer 504 on the semiconductor wafer 224 during the planarization operation 502. For example, the CMP controller 250 may determine that a material removal rate (e.g., a rate at which material is being removed from the layer 504 in the planarization operation 502) satisfies a threshold rate, and may determine to decrease the rotational velocity for the semiconductor wafer 224 in the planarization operation 502 based on determining that the material removal rate satisfies the threshold rate. As another example, the CMP controller 250 may determine that the material removal rate does not satisfy the threshold rate, and may determine to increase the rotational velocity for the semiconductor wafer 224 in the planarization operation 502 based on determining that the material removal rate does not satisfy the threshold rate.

In some implementations, the CMP controller 250 determines, based on monitoring the thickness of the layer 504 on the semiconductor wafer 224 during the planarization operation 502, a modified downward force for pressing the semiconductor wafer 224 against the polishing pad 204 in the planarization operation 502. For example, the CMP controller 250 may determine that the material removal rate for the layer 504 satisfies a threshold rate, and may determine to decrease the downward force for the semiconductor wafer 224 in the planarization operation 502 based on determining that the material removal rate satisfies the threshold rate. As another example, the CMP controller 250 may determine that the material removal rate does not satisfy the threshold rate, and may determine to increase the downward force for the semiconductor wafer 224 in the planarization operation 502 based on determining that the material removal rate does not satisfy the threshold rate.

In some implementations, the CMP controller 250 determines, based on monitoring the thickness of the layer 504 on the semiconductor wafer 224 during the planarization operation 502, a modified polishing path along which the semiconductor wafer 224 traverses in the planarization operation 502. In some implementations, the CMP controller 250 determines, based on monitoring the thickness of the layer 504 on the semiconductor wafer 224 during the planarization operation 502, a modified rotational velocity for the polishing pad 204 in the planarization operation 502.

Additionally and/or alternatively to determining modified parameters for the planarization operation 502, the CMP controller 250 may determine a completion time for the planarization operation 502 based on monitoring the thickness of the layer 504 during the planarization operation 502. The completion time corresponds to a time at which the CMP controller 250 determines that planarization of the layer 504 in the planarization operation 502 is complete. The CMP controller 250 may determine the completion time based on a threshold for the thickness of the layer 504. For example, the CMP controller 250 may determine the completion time as the time at which the thickness of the layer 504, as monitored during the planarization operation 502, satisfies the threshold. The threshold for the thickness of the layer 504 may correspond to a target thickness or a final thickness that is to be achieved by planarization the layer 504 in the planarization operation 502 for the layer 504. This highly granular level of detection, provided by the superconductor-based magnetometer device 260, enables the CMP controller 250 to determine the thickness of the layer 504 down to the angstrom-level, which enables the CMP controller 250 to end the planarization operation 502 with high precision for achieving the target thickness or the final thickness for the layer 504.

Moreover, the CMP controller 250 may use a machine learning model to identify the trends and/or to determine the one or more modified parameters based on monitoring the thickness of the layer 504 using the superconductor-based magnetometer device 260 during the planarization operation 502. In some implementations, the CMP controller 250 uses the machine learning model to determine the one or more modified parameters by providing candidate modified parameters as input to the machine learning model, and using the machine learning model to determine a predicted or estimated change in material removal rate for the layer 504, and a probability or confidence that the candidate modified parameters will achieve the predicted or estimated material removal rate. In some implementations, the CMP controller 250 provides a target material removal rate as input to the machine learning model, and the CMP controller 250 uses the machine learning model to determine or identify a particular combination of modified parameters for the planarization operation 502 that are estimated to achieve the target material removal rate.

The CMP controller 250 (or another system) may train, update, and/or refine the machine learning model to increase the accuracy of the outcomes and/or parameters determined using the machine learning model. The CMP controller 250 (or another system) may train, update, and/or refine the machine learning model based on feedback and/or results from historical and/or subsequent planarization operations (e.g., from hundreds, thousands, or more historical and/or subsequent planarization operations) performed by the planarization tool 100 in which the thickness of similar layers are monitored using the superconductor-based magnetometer device 260.

As shown in FIG. 5C, the CMP controller 250 may provide one or more signals 512, based on the one or more modified parameters, to the motor assembly 240 to control the planarization tool 100 during the planarization operation 502 to achieve the one or more modified parameters. The one or more signals 512 may include a voltage signal, a current signal, a digital communication, and/or another type of electrical signal.

In some implementations, the CMP controller 250 provides the one or more signals 512 to the motor assembly 240 to modify (e.g., increase, decrease) the downward force of the semiconductor wafer 224 against the polishing pad 204 based on a modified downward force parameters. The one or more signals 512 may enable control of the downward force in a range of approximately 1 pound per square inch (psi) to approximately 400 psi. However, other values for the range are within the scope of the present disclosure.

In some implementations, the CMP controller 250 provides the one or more signals 512 to the motor assembly 240 to modify (e.g., increase, decrease) the rotational velocity of the semiconductor wafer 224 in the planarization operation 502 based on a modified rotational velocity parameter. In some implementations, the CMP controller 250 provides the one or more signals 512 to the motor assembly 240 to modify (e.g., increase, decrease) the rotational velocity of the polishing pad 204 in the planarization operation 502 based on a modified rotational velocity parameter. In some implementations, the CMP controller 250 provides the one or more signals 512 to the motor assembly 240 to modify the polishing path that is traversed by the semiconductor wafer 224 in the planarization operation 502 based on a modified polishing path parameter.

Additionally and/or alternatively, the CMP controller 250 provides the one or more signals 512 to the motor assembly 240 to cause the planarization operation 502 to be ended. For example, the CMP controller 250 may determine, based on monitoring the thickness of the layer 504 using superconductor-based magnetometer device 260 during the planarization operation 502, that the thickness of the layer 504 satisfies the threshold. The CMP controller 250 may determine, based on determining that the thickness of the layer 504 satisfies the threshold, that the target thickness or final thickness for the layer 504 has been achieved and, therefore, the planarization operation 502 is complete. Accordingly, the CMP controller 250 may provide the one or more signals 512 to the motor assembly 240 to remove the semiconductor wafer 224 from being pressed against the polishing pad 204 based on determining that the planarization operation 502 is complete.

As indicated above, FIGS. 5A-5C are provided as an example. Other examples may differ from what is described with regard to FIGS. 5A-5C.

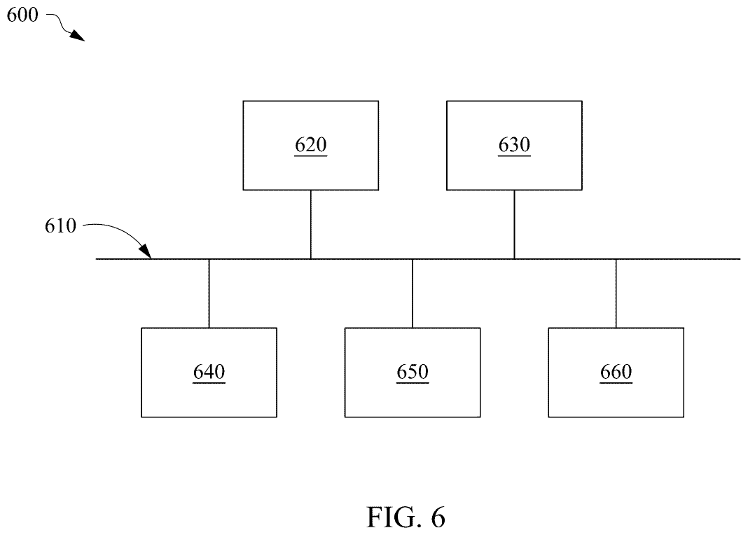

FIG. 6 is a diagram of example components of a device 600 described herein. The device 600 may correspond to the planarization tool 100, the motor assembly 240, and/or the CMP controller 250, among other examples. In some implementations, the planarization tool 100, the motor assembly 240, and/or the CMP controller 250, among other examples, may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

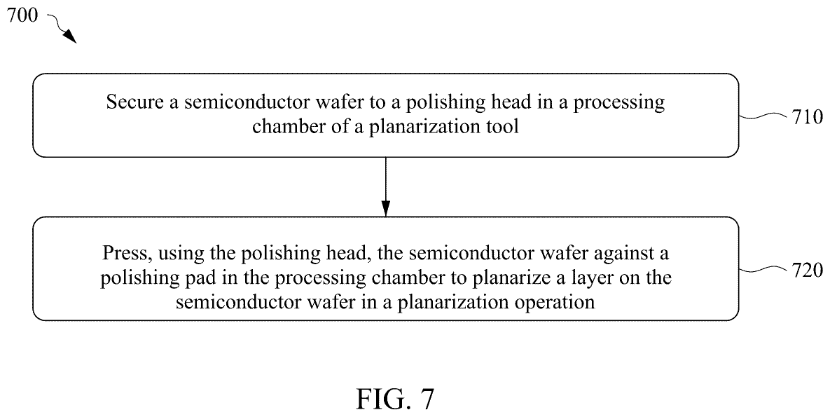

FIG. 7 is a flowchart of an example process 700 associated with a planarization operation described herein. In some implementations, one or more process blocks of FIG. 7 are performed by a planarization tool 100 (e.g., planarization tool 100). In some implementations, one or more process blocks of FIG. 7 are performed by another device or a group of devices separate from or including the planarization tool 100, such as a motor assembly (e.g., the motor assembly 240) and/or a CMP controller (e.g., the CMP controller 250), among other examples. Additionally, or alternatively, one or more process blocks of FIG. 7 may be performed by one or more components of device 600, such as processor 620, memory 630, input component 640, output component 650, and/or communication component 660.

As shown in FIG. 7, process 700 may include securing a semiconductor wafer to a polishing head in a processing chamber of a planarization tool (block 710). For example, a semiconductor wafer 224 may be secured to a polishing head 222 in a processing chamber 102 of the planarization tool 100, as described herein.

As further shown in FIG. 7, process 700 may include pressing, using the polishing head, the semiconductor wafer against a polishing pad in the processing chamber to planarize a layer on the semiconductor wafer in a planarization operation (block 720). For example, the planarization tool 100 may press, using the polishing head 222, the semiconductor wafer 224 against a polishing pad 204 in the processing chamber 102 to planarize a layer 504 on the semiconductor wafer 224 in a planarization operation 502, as described herein.

Process 700 may include additional implementations, such as any single implementation or any combination of implementations described below and/or in connection with one or more other processes described elsewhere herein.

In a first implementation, a thickness of the layer 504 is monitored during the planarization operation 502 using a superconductor-based magnetometer device 260. In a second implementation, alone or in combination with the first implementation, one or more parameters of the planarization operation 502 are modified during the planarization operation 502 based on a change in the thickness of the layer 504 as monitored during the planarization operation 502. In a third implementation, alone or in combination with the first or second implementation, the one or more parameters include a rotational velocity of the semiconductor wafer 224, a downward force that is used to press the semiconductor wafer 224 against the polishing pad 204, or a polishing path along which the semiconductor wafer 224 traverses in the planarization operation 502.

In a fourth implementation, alone or in combination with one or more of the first through third implementations, a machine learning model is used to modify the one or more parameters of the planarization operation 502 based on the change in the thickness of the layer 504 as monitored during the planarization operation 502. In a fifth implementation, alone or in combination with one or more of the first through fourth implementations, the thickness of the layer 504 is monitored based on a voltage signal (e.g., a signal 308), and the voltage signal is based on a voltage drop across the superconductor-based magnetometer device 260. In a sixth implementation, alone or in combination with one or more of the first through fifth implementations, a magnitude of the voltage drop across the superconductor-based magnetometer device 260 is based on a field strength of an induced magnetic field 304, and the field strength of the induced magnetic field 304 is based on the thickness of the layer 504.

In a seventh implementation, alone or in combination with one or more of the first through sixth implementations, a magnitude of the voltage drop across the superconductor-based magnetometer device 260 is based on a field strength of an induced magnetic field 304, and the induced magnetic field 304 is generated as the semiconductor wafer 224 moves through an applied magnetic field 302 during the planarization operation 502. In an eighth implementation, alone or in combination with one or more of the first through seventh implementations, the applied magnetic field 302 causes an eddy current to be induced in the layer 504 on the semiconductor wafer 224 as the semiconductor wafer moves through the applied magnetic field 302, and the eddy current causes the induced magnetic field 304 to be generated. In a ninth implementation, alone or in combination with one or more of the first through eighth implementations, the applied magnetic field 302 is generated by providing a direct current or an alternating current through a conductive coil 270 in the processing chamber 102.

In a tenth implementation, alone or in combination with one or more of the first through ninth implementations, a completion time for the planarization operation 502 is based on a threshold for a thickness of the layer 504, and the thickness of the layer 504 is monitored during the planarization operation 502 using the superconductor-based magnetometer device 260. In an eleventh implementation, alone or in combination with one or more of the first through tenth implementations, the thickness of the layer 504 is monitored based on a voltage drop across the superconductor-based magnetometer device 260, and a magnitude of the voltage drop across the superconductor-based magnetometer device 260 is based on a field strength of an induced magnetic field 304, where the induced magnetic field 304 is generated as the semiconductor wafer 224 moves through an applied magnetic field 302 during the planarization operation 502.

In a twelfth implementation, alone or in combination with one or more of the first through eleventh implementations, the applied magnetic field 302 causes an eddy current to be induced in the layer 504 on the semiconductor wafer 224 as the semiconductor wafer 224 moves through the applied magnetic field 302, and the field strength of the induced magnetic field 304 is based on a magnitude of the eddy current induced in the layer 504 on the semiconductor wafer 224. In a thirteenth implementation, alone or in combination with one or more of the first through twelfth implementations, the magnitude of the eddy current induced in the layer 504 on the semiconductor wafer 224 is based on the thickness of the layer 504.

In a fourteenth implementation, alone or in combination with one or more of the first through thirteenth implementations, the magnitude of the eddy current induced in the layer 504 on the semiconductor wafer 224 is based on a rotational velocity of the semiconductor wafer 224. In a fifteenth implementation, alone or in combination with one or more of the first through fourteenth implementations, the magnitude of the eddy current induced in the layer 504 on the semiconductor wafer 224 is based on a distance between the semiconductor wafer 224 and a conductive coil 270 that is used to generate the applied magnetic field 302.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a planarization tool is configured to monitor one or more operational parameters of the planarization tool. The planarization tool may include a superconductor-based monitoring system that is configured to monitor a thickness of a layer on a semiconductor wafer that is processed by the planarization tool. The superconductor-based monitoring system may include a superconductor-based sensor that is configured to generate a signal that is based on an induced magnetic field through the layer on the semiconductor wafer. The signal may be provided to a CMP controller of the planarization tool. The CMP controller may determine a thickness of the layer based on the signal. The CMP controller may provide one or more control signals to the polishing head to control one or more operational parameters such as a down force of the semiconductor wafer against the polishing pad and/or a rotational speed of the semiconductor wafer against the polishing pad, among other examples.

As described in greater detail above, some implementations described herein provide a method. The method includes securing a semiconductor wafer to a polishing head in a processing chamber of a planarization tool. The method includes pressing, using the polishing head, the semiconductor wafer against a polishing pad in the processing chamber to planarize a layer on the semiconductor wafer in a planarization operation, where a thickness of the layer is monitored during the planarization operation using a superconductor-based magnetometer device.

As described in greater detail above, some implementations described herein provide a method. The method includes securing a semiconductor wafer to a polishing head in a processing chamber of a planarization tool. The method includes pressing, using the polishing head, the semiconductor wafer against a polishing pad in the processing chamber to planarize a layer on the semiconductor wafer in a planarization operation, where a completion time for the planarization operation is based on a threshold for a thickness of the layer, and where the thickness of the layer is monitored during the planarization operation using a superconductor-based magnetometer device.

As described in greater detail above, some implementations described herein provide a planarization tool. The planarization tool includes a processing chamber. The planarization tool includes a platen in the processing chamber, where the platen is configured to support a polishing pad in the processing chamber. The planarization tool includes a polishing head configured, support a semiconductor wafer, and press the semiconductor wafer against the polishing pad. The planarization tool includes a superconductor-based magnetometer device, in the processing chamber, configured to directly detect an induced magnetic field that is induced in a layer on the semiconductor wafer during a planarization operation performed by the planarization tool.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A planarization tool, comprising:
a processing chamber;
a platen in the processing chamber,
wherein the platen is configured to support a polishing pad in the processing chamber;
a polishing head configured to:
support a semiconductor wafer, and
press the semiconductor wafer against the polishing pad; and
a superconductor-based magnetometer device, in the processing chamber, configured to directly detect an induced magnetic field that is induced in a layer on the semiconductor wafer during a planarization operation performed by the planarization tool.

2. The planarization tool of claim 1, wherein the superconductor-based magnetometer device comprises a superconducting quantum interference device.

3. The planarization tool of claim 1, wherein the superconductor-based magnetometer device comprises:
a first superconductor element;
a second superconductor element; and
an insulator layer between the first superconductor element and the second superconductor element.

4. The planarization tool of claim 3, wherein the first superconductor element and the second superconductor element each include at least one of:
niobium tin (Nb₃Sn),
niobium titanium (NbTi),
barium copper oxide (BCO), or
rare earth (RE) BCO ((RE)BCO).

5. The planarization tool of claim 1, further comprising:
a controller configured to:
determine a magnitude of a voltage drop across the superconductor-based magnetometer device based on a field strength of the induced magnetic field; and
determine a thickness of the layer on the semiconductor wafer based on the magnitude of the voltage drop.

6. A planarization tool, comprising:
a processing chamber comprising a platen in the processing chamber configured to support a polishing pad;
a polishing head configured to support a semiconductor wafer and press the semiconductor wafer against the polishing pad during a planarization operation;
a superconductor-based monitoring system, comprising a superconducting quantum interference device (SQUID) configured to detect an induced magnetic field generated in a layer on the semiconductor wafer; and
a controller configured to:
determine a thickness of the layer on the semiconductor wafer based on a signal generated by the SQUID, and
control an operational parameter of the planarization tool based on the thickness.

7. The planarization tool of claim 6, wherein the operational parameter comprises at least one of:
a downward force applied by the polishing head, or
a rotational speed of the semiconductor wafer.

8. The planarization tool of claim 6, further comprising:
a conductive coil configured to generate an applied magnetic field that induces an eddy current in the layer on the semiconductor wafer.

9. The planarization tool of claim 6, wherein the signal is based on a field strength of the induced magnetic field.

10. The planarization tool of claim 6, wherein the controller is further configured to:
determine a completion time for the planarization operation based on the thickness of the layer and the operational parameter.

11. The planarization tool of claim 6, wherein the SQUID comprises:
a first superconductor element;
a second superconductor element; and
an insulator layer between the first superconductor element and the second superconductor element.

12. The planarization tool of claim 11, wherein the signal corresponds to a voltage drop across the first superconductor element, the second superconductor element, and the insulation layer.

13. The planarization tool of claim 11, wherein the signal corresponds to a current drop across the first superconductor element, the second superconductor element, and the insulation layer.

14. The planarization tool of claim 6, wherein the superconductor-based monitoring system is configured to:
detect angstrom-level changes in the thickness of the layer on the semiconductor wafer,
wherein the signal indicates the angstrom-level changes.

15. A planarization tool, comprising:
a processing chamber comprising a platen configured to support a polishing pad;
a polishing head configured to press a semiconductor wafer against the polishing pad;
a conductive coil configured to generate an applied magnetic field that induces an eddy current in a layer on the semiconductor wafer during a planarization operation;
a superconducting quantum interference device (SQUID) configured to directly detect an induced magnetic field generated by the eddy current; and
a controller configured to:
determine a thickness of the layer based on the induced magnetic field, and
dynamically adjust a polishing parameter of the planarization tool during the planarization operation based on the determined thickness.

16. The planarization tool of claim 15, wherein the polishing parameter comprises at least one of:
a rotational speed of the polishing pad,
a rotational speed of the semiconductor wafer,
a polishing path, or
a downward force of the polishing head.

17. The planarization tool of claim 15, wherein the controller is further configured to:
terminate the planarization operation when the determined thickness satisfies a threshold thickness.

18. The planarization tool of claim 15, wherein the conductive coil comprises a superconductive material including at least one of niobium tin (Nb₃Sn), niobium titanium (NbTi), barium copper oxide (BCO), or rare earth BCO ((RE)BCO).

19. The planarization tool of claim 15, wherein the SQUID is further configured to output a voltage signal proportional to a field strength of the induced magnetic field.

20. The planarization tool of claim 15, wherein the controller is further configured to:
select, using a machine learning model and based on the thickness, the polishing parameter.
